(19) United States
(12) Patent Application Publication
(10) Pub. No.: US 2011/0114381 A1
(43) Pub. Date: May 19, 2011

(54) Electromagnetic Frequency Radiation for Non-Ionizing Radiation Harmonizer and method of use

(76) Inventor: Rhoda Zione Alale, Wilmington, OH (US)

(21) Appl. No.: 12/949,519

(22) Filed: Nov. 18, 2010

Related U.S. Application Data
(60) Provisional application No. 61/262,149, filed on Nov. 18, 2009.

(51) Int. Cl. H05K 9/00

(52) U.S. Cl. 174/377

(57) ABSTRACT

The present invention is an electromagnetic frequency and non-ionizing radiation harmonizer that can be a film, a sheet or a textile that harmonizes or mitigates electromagnetic frequency (EMF) radiation from non-ionizing EMF emitting devices while allowing an integration of vibrations or frequency mediums. The invention also includes a method of using an electromagnetic frequency radiation and non-ionizing radiation harmonizer that includes the steps of obtaining a film, a sheet or a textile that harmonizes or mitigates electromagnetic frequency (EMF) radiation from one or more non-ionizing EMF emitting devices and disposing the film, sheet or textile in direct contact or within dose proximity of one or more non-ionizing EMF emitting devices.

This application claims priority to U.S. Provisional Application 61/262,149 filed on Nov. 18, 2009, the entire disclosure of which is incorporated by reference.

### TECHNICAL FIELD & BACKGROUND

Research directly shows a correlation of electromagnetic frequency radiation (EMF) from electronics and power transformers such as cell phones, wireless fidelity (IEEE 802.11b wireless networking) or WIFI related devices, computers and appliances and to diseases such as acoustic neuroma (hearing loss), autism, fibromyalgia and others, prompting two new classes of diagnoses, electromagnetic hypersensitivity (EHS) and multiple chemical sensitivity (MCS). Prominent cellular and biomedical engineers agree that sustained exposure to EMF radiation causing EHS and MCS can contribute to causing autism and other diseases. Additionally, homes built in geographic areas where radioactive chemicals are in the ground are relatively more at risk for having high levels of electromagnetic static radiation in the electrical currents of the homes in those geographic areas.

The present invention generally relates to a radiation harmonizer. More specifically, the invention is an electromagnetic frequency radiation for non-ionizing radiation harmonizer in various sheet, film and textile forms.

It is an object of the invention to provide an electromagnetic frequency radiation for non-ionizing radiation harmonizer that causes the electrons of EMF radiation to spin forward allowing the EMF radiation to be in natural harmony with the biorhythm of healthy cells of a person's body.

It is an object of the invention to provide an electromagnetic frequency radiation for non-ionizing radiation harmonizer that allows for harmonization or mitigation of EMF radiation in non-ionizing EMF energized electronic devices and appliances such as cell phones, household appliances, energized machinery, electrical wall currents, medical technology devices, lamps, fuse boxes, WIFI related devices, televisions, medical electrical devices, automotive electric devices, telecommunications devices and electronic components in aircraft.

It is an object of the invention to provide multiple electromagnetic frequency radiation for non-ionizing radiation harmonizers that can be used for harmonizing or clearing static electromagnetic frequency radiation.

It is an object of the invention to provide a multiple electromagnetic frequency radiation for non-ionizing radiation harmonizer that rebalances kinetic energy in the cells of a person's body.

What is really needed is a multiple electromagnetic frequency radiation for non-ionizing radiation harmonizer that causes the electrons of EMF radiation to spin forward allowing the EMF radiation to be in natural harmony with the biorhythm of healthy cells of a body exposed to the EMF radiation, that allows for harmonization or mitigation of EMF radiation in non-ionizing EMF energized electronic devices and appliances such as cell phones, household appliances, energized machinery, electrical wall currents, medical technology devices, lamps, fuse boxes, WIFI related devices, televisions, medical electrical devices, automotive electric devices, telecommunications devices and electronic components in aircraft as well as harmonizing or clearing static electromagnetic frequency radiation that rebalances kinetic energy in the cells of a person's body.

### BRIEF DESCRIPTION OF THE DRAWINGS

The present invention will be described by way of exemplary embodiments, but not limitations, illustrated in the accompanying drawings in which like references denote similar elements, and in which:

FIG. 1 is an overhead perspective view of an electromagnetic frequency radiation for non-ionizing radiation harmonizer, in accordance with one embodiment of the present invention.

FIG. 2 is a flowchart for a method of using an electromagnetic frequency radiation for non-ionizing radiation harmonizer, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

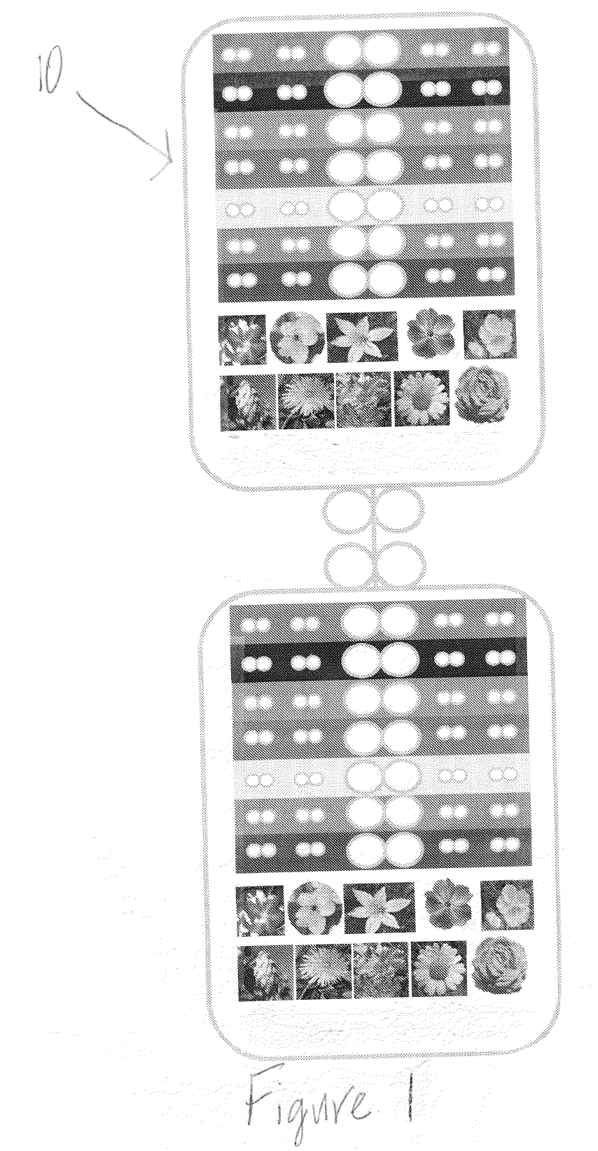

FIG. 1 is an overhead perspective view of an electromagnetic frequency radiation for non-ionizing radiation harmonizer 10, in accordance with one embodiment of the present invention. The electrons in healthy cells naturally spin freely in one direction. When the electrons of those healthy cells are directly exposed to EMF radiation, such as when a cell phone is in a person's ear (not shown), the exposed electrons spin changes from the EMF radiation frequencies. This unnatural spin reduces the cell's micro-voltage during the EMF radiation exposure time and long-term EMF radiation exposure has shown to produce a reduction of a healthy cell's overall energy, often resulting in various diseases such as cancer, chronic fatigue, fibromyalgia, impairment of cell apoptosis or cell death of abnormal tissue which can cause autism and other diseases.

The electromagnetic frequency radiation for non-ionizing radiation harmonizer 10 was made to help protect persons who are exposed to levels of EMF radiation in their home and in convergence with EMF radiating devices. A problem with EMF radiation is that the electrons from the EMF radiation spin backwards and knock the bio-rhythms of the healthy cells of a person's body out of sync, causing healthy cells of the body, especially the red blood cells, to clump or aggregate and their electrons to spin backwards also. The kinetic energy of the electrons of healthy cells typically spin forward and the backward spinning of the electrons of these healthy cells can de-mineralize these healthy cells causing disease, including but not limited to cancer, chronic fatigue, fibromyalgia, impairment of cell apoptosis or cell death of abnormal tissue, which can cause autism or other previously mentioned diseases.

The electromagnetic frequency radiation for non-ionizing radiation harmonizer 10 causes the EMF radiation to spin forward thereby allowing it to be in natural harmony with the biorhythm of the healthy cells of the body. It allows for a harmonization or mitigation of EMF radiation in non-ionizing EMF energized electronics, appliances and devices at any milliGauss measurement which can range from 0.0001 mG to 10 mG or above such as found in cell phones, household appliances, energized machinery, electrical wall currents, medical technology devices, lamps, fuse boxes, WIFI related devices, televisions, medical electrical devices, automotive electric devices, telecommunications devices and electronic components in aircraft. Multiple electromagnetic frequency radiation for non-ionizing radiation harmonizers 10 can be used to get the desired effects of harmonizing electromagnetic fields including but not limited to, cell phones, household appliances, energized machinery, electrical wall currents, medical technology devices, lamps, fuse boxes, WIFI related devices, televisions, medical electrical devices, automotive electric devices, telecommunications devices and electronic components in aircraft, as well as harmonizing or clearing static electromagnetic frequency radiation and rebalancing kinetic energy in the cells of the body.

The electromagnetic frequency radiation for non-ionizing radiation harmonizer 10 allows for the integration of vibrations or frequency mediums including colors, geometric shapes, flowers, plants, foods, water, stones, metal, music, videos, plastics and audio sounds that can be conducted through heat and chemical processing to potentiate textiles that include paper, fabric, plastics, metals or other materials that are well known in the art.

The thickness of the electromagnetic frequency radiation for non-ionizing radiation harmonizer 10 can range from a thin film of any size such as 1/100 of an inch to approximately 2 inches, allowing for adaptation of virtually every type of electronic device, including cell phones, household appliances, energized machinery, electrical wall currents, medical technology devices, lamps, fuse boxes, WIFI related devices, televisions, medical electrical devices, automotive electric devices, telecommunications devices and electronic components in aircraft that are well known in the art. The electromagnetic frequency radiation for non-ionizing radiation harmonizer 10 can be any length to adjust to any size of EMF radiation emitting electronic device. The electromagnetic frequency radiation for non-ionizing radiation harmonizer 10 can be in direct contact or be disposed within one inch or more of any electronic device emitting EMF radiation that needs to be harmonized. The electromagnetic frequency radiation for non-ionizing radiation harmonizer 10 can be placed on a person's body and it will harmonize static EMF radiation being exposed to that person's body. The electromagnetic frequency radiation for non-ionizing radiation harmonizer 10 can be used for cell phones, household appliances, energized machinery, electrical wall currents, medical technology devices, lamps, fuse boxes, WIFI related devices, televisions, medical electrical devices, automotive electric devices, telecommunications devices and electronic components in aircraft and other devices that are well known in the art that emit EMF radiation.

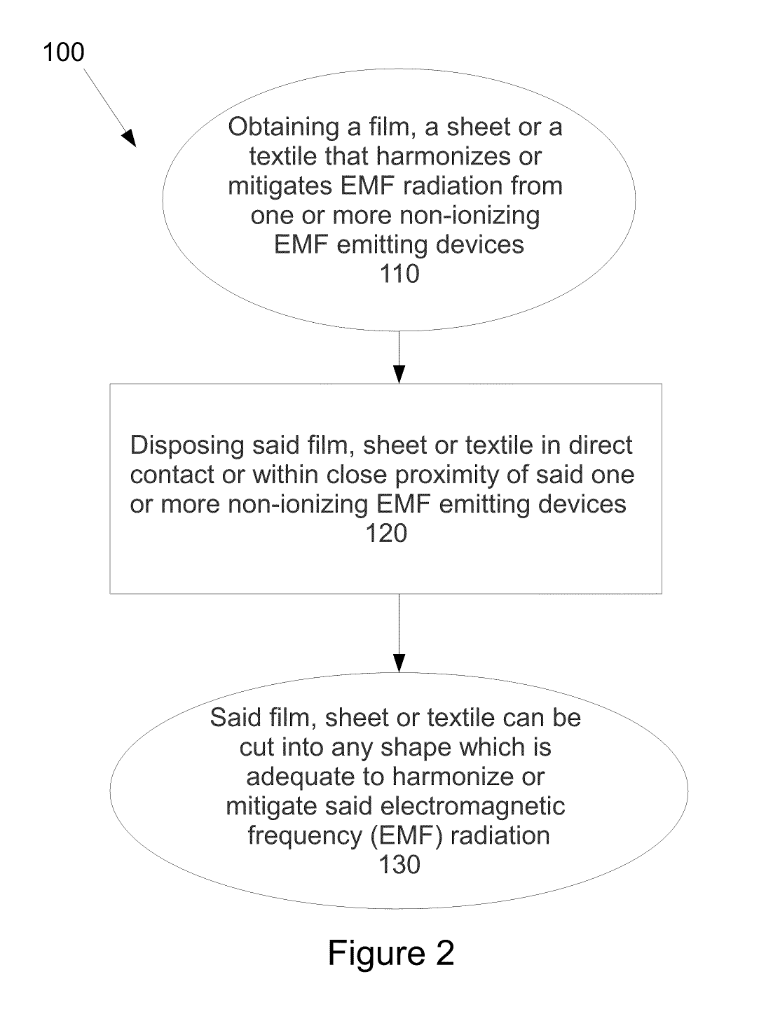

FIG. 2 is a flowchart illustrating a method for using an electromagnetic frequency radiation for non-ionizing radiation harmonizer 100, in accordance with one embodiment of the present invention. The steps of the method for using an electromagnetic frequency radiation for non-ionizing radiation harmonizer 100 include obtaining a film, a sheet or a textile that harmonizes or mitigates electromagnetic frequency (EMF) radiation from one or more non-ionizing EMF emitting devices 110 and disposing the film, sheet or textile in direct contact or within close proximity of one or more non-ionizing EMF emitting devices 120.

Use of the electromagnetic frequency radiation for non-ionizing radiation harmonizer 10 is straightforward. The electromagnetic frequency radiation for non-ionizing radiation harmonizer 10 can be used in a variety of sizes such as ¼ inch and higher. The electromagnetic frequency radiation and non-ionizing radiation harmonizer 10 can be in the form of plastic sheets 8.5″×11″, or any size film, sheet or textile that can also be cut into any size or shape which is adequate for harmonizing the emitting EMF radiation that it is placed on or in proximity to an object or person to be protected. For example a ½″×3″ strip cut out of a 8.5″×11″ plastic sheet of electromagnetic frequency radiation and non-ionizing radiation harmonizer 10 may be adequate for protecting a user from EMF radiation from a cell phone. Other thicker electromagnetic frequency radiation for non-ionizing radiation harmonizer 10 materials can also be used for higher exposures of EMF radiation including but not limited to measurements below or above 0.0001 milliGauss such as films, sheets and textiles that are well known in the art.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

What is claimed is:

1. An electromagnetic frequency and non-ionizing radiation harmonizer, comprising:
a film; a sheet or a textile that harmonizes or mitigates electromagnetic frequency (EMF) radiation from non-ionizing EMF emitting devices while allowing an integration of vibrations or frequency mediums from other sources.

2. The harmonizer according to claim 1, wherein said electromagnetic frequency radiation for non-ionizing radiation harmonizer harmonizes or mitigates said EMF radiation in non-ionizing EMF emitting devices above 0.0001 milliGauss.

3. The harmonizer according to claim 2, wherein said non-ionizing EMF emitting devices including cell phones, household appliances, energized machinery, electrical wall currents, medical technology devices, lamps, fuse boxes, WIFI related devices, televisions, medical electrical devices, automotive electric devices, telecommunications devices and electronic components in aircraft.

4. The harmonizer according to claim 3, wherein said telephones include cell phones, cordless phones and land line phones.

5. The harmonizer according to claim 1, wherein said electromagnetic frequency and non-ionizing radiation harmonizer causes said electrons of EMF radiation to spin forward.

6. The harmonizer according to claim 1, wherein said electromagnetic frequency and non-ionizing radiation harmonizer can harmonize or clear static electromagnetic frequency radiation.

7. The harmonizer according to claim 1, wherein said electrons of EMF radiation are in a natural harmony with a plurality and polarity of healthy cells of a person's body.

8. The harmonizer according to claim 1, wherein said electromagnetic frequency and non-ionizing radiation harmonizer can range in thickness from less than 1/100^{th} of an inch to approximately 2 inches.

9. The harmonizer according to claim 1, wherein said other sources of vibrations or frequency mediums include colors, geometric shapes, flowers, plants, foods, water, stones, metal, music, videos, plastics and audio sounds that can be conducted through heat and chemical processing.

10. A method of using an electromagnetic frequency radiation and non-ionizing radiation harmonizer, comprising:
obtaining a film, a sheet or a textile that harmonizes or mitigates electromagnetic frequency (EMF) radiation from one or more non-ionizing EMF emitting devices; and
disposing said film, sheet or textile in direct contact or within close proximity of said one or more non-ionizing EMF emitting devices.

11. The method according to claim 10, wherein said film, sheet or textile can be cut into any shape which is adequate to harmonize or mitigate said electromagnetic frequency (EMF) radiation.

12. The method according to claim 10, wherein said electromagnetic frequency radiation and non-ionizing radiation harmonizer harmonizes or mitigates said EMF radiation in non-ionizing EMF emitting devices above 0.0001 milliGauss.

13. The method according to claim 12, wherein said electromagnetic frequency and non-ionizing radiation harmonizer causes said electrons of EMF radiation to spin forward.

14. The method according to claim 10, wherein said electrons of EMF radiation are in a natural harmony with a plurality and polarity of healthy cells of a person's body.

15. The method according to claim 10, wherein said non-ionizing EMF emitting devices include to cell phones, household appliances, energized machinery, electrical wall currents, medical technology devices, lamps, fuse boxes, WIFI related devices, televisions, medical electrical devices, automotive electric devices, telecommunications devices and electronic components in aircraft.

16. The method according to claim 15, wherein said telephones include cell phones, cordless phones, land line phones and batteries for all telecommunication technologies.

17. The harmonizer according to claim 10, wherein said electromagnetic frequency and non-ionizing radiation harmonizer can harmonize or clear static electromagnetic frequency radiation.

18. The method according to claim 10, wherein said electromagnetic frequency and non-ionizing radiation harmonizer can range in thickness from a less than 1/100^{th} of an inch to approximately 2 inches.
